(19) United States
(12) Patent Application Publication
(10) Pub. No.: US 2013/0292629 A1
(43) Pub. Date: Nov. 7, 2013

(54) PHASE CHANGE MEMORY CELL AND FABRICATION METHOD THEREOF

(71) Applicants: Bo Liu, Shanghai (CN); Zhitang Song, Shanghai (CN); Ting Zhang, Shanghai (CN); Ying Li, Shanghai (CN); Min Zhong, Shanghai (CN); Songlin Feng, Shanghai (CN)

(72) Inventors: Bo Liu, Shanghai (CN); Zhitang Song, Shanghai (CN); Ting Zhang, Shanghai (CN); Ying Li, Shanghai (CN); Min Zhong, Shanghai (CN); Songlin Feng, Shanghai (CN)

(21) Appl. No.: 13/202,697

(22) PCT Filed: Jun. 23, 2011
(86) PCT No.: PCT/CN11/76239

§ 371 Date: Aug. 22, 2011

(30) Foreign Application Priority Data
Jan. 18, 2011 (CN) 201110020727.2

(51) Int. Cl. H01L 45/00

(52) U.S. Cl. CPC H01L 45/1253; H01L 45/16
USPC 257/4; 438/381

(57) ABSTRACT

The present invention provides a phase change memory cell and fabrication method thereof, wherein said phase change memory cell comprises a semiconductor substrate, a first electrode layer, a phase change material layer, a second electrode layer and an extraction electrode, as well as a high resistance material layer used to prevent said phase change material layer from over-corrosion during the chemical mechanical polishing process, and wherein said high resistance material layer has a resistance ten or more times that of the phase change material layer and can be used to prevent phase change material layer from over-corrosion during the chemical mechanical polishing process and thus enhance the memory performance and the yield of phase change memory cell.

### FIELD OF THE INVENTION

The present invention relates to a phase change memory technology, and more particularly to a phase change memory cell involving high resistance material and fabrication method thereof.

### BACKGROUND OF THE INVENTION

Phase change memory (also known as phase change random access memory, PC-RAM), a type of non-volatile semiconductor memories emerging in recent years, is a type of memory devices with low price and stable performance, built on the concept that phase change thin film can be applied to phase change memory medium, which was proposed by Ovshinsky in the late 1960s (Phys. Rev. Lett., 21, 1450˜1453, 1968) and early 1970s (Appl. Phys. Lett., 18, 254˜257, 1971). Phase change memory can be fabricated on silicon wafer substrate, wherein the key materials are recordable phase change material thin films, heating electrode materials, heat-insulating materials, extraction electrode materials and etc. The basic principle of phase change memory is to apply electric pulse signals on device cells to induce reversible phase change between amorphous and polycrystalline states and realize information write, erase and read operations by discerning between the high resistance, amorphous state and low resistance, polycrystalline state.

Compared with various kinds of semiconductor memory technologies of the day, phase change memory has advantages of low power consumption, high density, anti-radiation, non-volatility, high-speed read, long cycle life (>10¹³ times), device size scalability (nano-scale), high and low temperature resistance (−55° C. to 125° C.), vibration proof, anti-electronic interference and simple process (compatible with current integrated circuit processes). Therefore, it is universally regarded as the most competitive one of the next generation of memories in industry, enjoying extensive market prospect.

Research on memory has been developed in the direction of high speed, high density, low power consumption and high reliability. Currently, organizations that are engaged in research and development of phase change memory are mainly large corporations in semiconductor field, with the concerns fully on how to rapidly realize the industrialization of phase change memory. Two main kinds of processes are involved in the processing of phase change materials during the fabrication of phase change memory: etching and chemical mechanical polishing. During chemical mechanical polishing process, phase change material is removed due to over-corrosion (with the phase change material layer left very thin, as shown in FIG. 1, where the circled region is the phase change material layer), and even completely removed, which may result in the deterioration of phase change properties of phase change material and subsequent performance (e.g. information write, erase and read operations) degradation or even complete failure of phase change memory. The main reason lies in that the device loop aggravates the electrochemical corrosion and the lower the loop resistance, the greater the electrochemical corrosion.

### SUMMARY OF THE INVENTION

An object of the present invention is to provides a phase change memory cell and fabrication method thereof so as to solve the problem of performance degradation and even failure of phase change memory cell caused by over-corrosion of the phase change material in phase change memory during the process of chemical mechanical polishing in the prior art.

The present invention provides a phase change memory cell, comprising a semiconductor substrate, and a first electrode layer, a phase change material layer and a second electrode layer that are sequentially located on said semiconductor substrate, and an extraction electrode located on said semiconductor substrate as well as a high resistance material layer used to prevent said phase change material layer from over-corrosion during the chemical mechanical polishing process, wherein said high resistance material layer has a resistance ten or more times that of the phase change material layer.

Optionally, said high resistance material layer is located between said first electrode layer and said phase change material layer, or located on the extraction electrode of said first electrode layer.

Optionally, said high resistance material layer is made of any one of the following: simple substance of main group IV, V and VI, alloy, oxide, nitride, carbide, nitrogen oxide.

Optionally, said high resistance material layer has a thickness in the range of 1 nm to 50 nm.

The present invention further provides a fabrication method of phase change memory cell, comprising the following steps of: providing a semiconductor substrate and forming a first electrode layer and an extraction electrode on said semiconductor substrate; forming a phase change material layer on said first electrode layer and forming a high resistance material layer on said extraction electrode, wherein said high resistance material layer has a resistance ten or more times that of the phase change material layer; grinding said phase change material layer and removing the high resistance material layer on said extraction electrode; and integrating said first and second electrode layers with control switches, driving circuits and peripheral circuits by said extraction electrode to form a phase change memory cell.

Optionally, said high resistance material layer is made of any one of the following: simple substance of main group IV, V and VI, alloy, oxide, nitride, carbide, nitrogen oxide.

Optionally, said high resistance material layer has a thickness in the range of 10 nm to 50 nm.

The present invention further provides a fabrication method of phase change memory cell, comprising the following steps of: providing a semiconductor substrate and forming a first electrode layer and an extraction electrode on said semiconductor substrate; forming a high resistance material layer on said first electrode layer; forming a phase change material layer on said high resistance material layer and carrying out grinding, wherein said high resistance material layer has a resistance ten or more times that of the phase change material layer; forming a second electrode layer on said phase change material layer; and integrating said first and second electrode layers with control switches, driving circuits and peripheral circuits by said extraction electrode to form a phase change memory cell.

Optionally, said high resistance material layer is made of any one of the following: simple substance of main group IV, V and VI, alloy, oxide, nitride, carbide, nitrogen oxide.

Optionally, said high resistance material layer has a thickness in the range of 1 nm to 10 nm.

Compared with the prior art, the present invention provides a phase change memory cell with an extra high resistance material layer having a resistance ten or more times that of the phase change material layer to prevent the phase change material layer from over-corrosion during the chemical mechanical polishing process and thus enhance the memory performance and the yield of phase change memory cell.

### BRIEF DESCRIPTION OF THE DRAWINGS

FIG. 1 is a part sectional view of a phase change memory suffering from phase change material over-corrosion caused by electrochemical corrosion in the prior art;

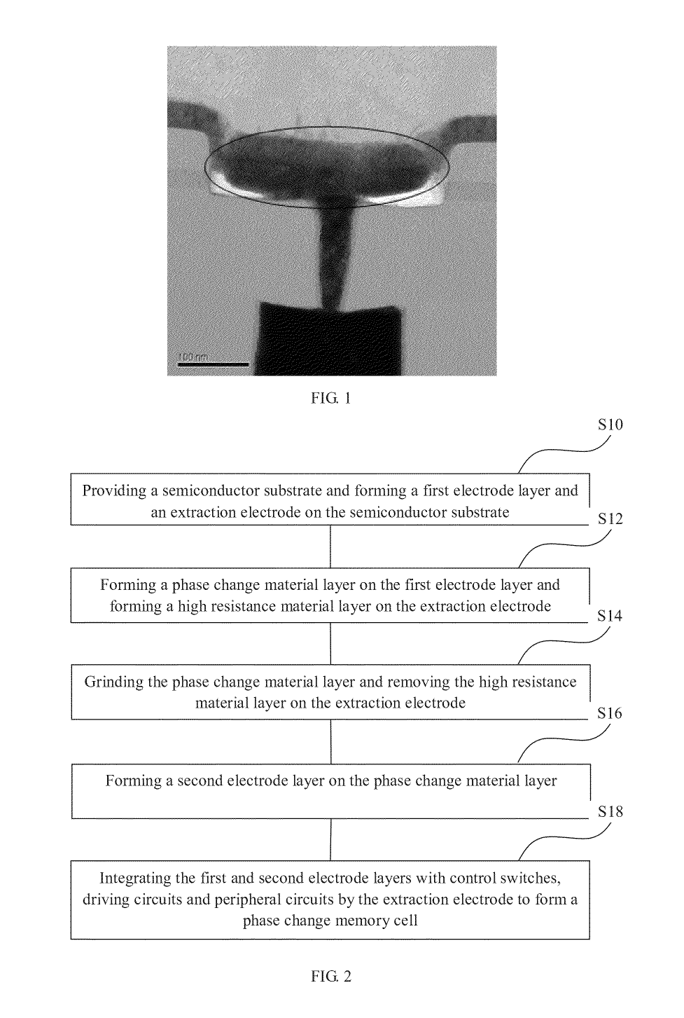

FIG. 2 is a schematic flowchart of a fabrication method of a phase change memory provided by the present invention in embodiment 1;

FIGS. 3-7 are schematic views of the structure of fabricating phase change memory cell according to the flow in FIG. 2;

FIG. 8 is a part sectional view of a phase change memory maintaining the structural integrity after chemical mechanical polishing;

FIG. 9 is a schematic flowchart of a fabrication method of a phase change memory provided by the present invention in embodiment 2;

FIG. 10-14 are schematic views of the structure of fabricating phase change memory cell according to the flow in FIG. 9.

### DETAILED DESCRIPTION OF THE EMBODIMENTS

The inventor of the present invention finds that, during chemical mechanical polishing process in the prior art, the device loop aggravates the electrochemical corrosion and the lower the loop resistance, the greater the electrochemical corrosion, so phase change material thereof suffers from over-corrosion and thus causes the functional failure of memory device.

Therefore, the inventor of the present invention improves the prior art by providing a novel phase change memory cell, wherein said phase change memory cell comprises a high resistance material layer used to prevent said phase change material layer from over-corrosion during the chemical mechanical polishing process. Said high resistance material layer has a resistance ten or more times that of the phase change material layer and can be used to solve the problem of phase change material over-corrosion during the chemical mechanical polishing process and thus enhance the memory performance and the yield of phase change memory cell.

The substantial characteristics of the present invention are further detailed below with reference to specific embodiments, however the present invention is not only restricted to the embodiments, that is to say, the embodiments described are not a limitation of the present invention.

### Embodiment 1

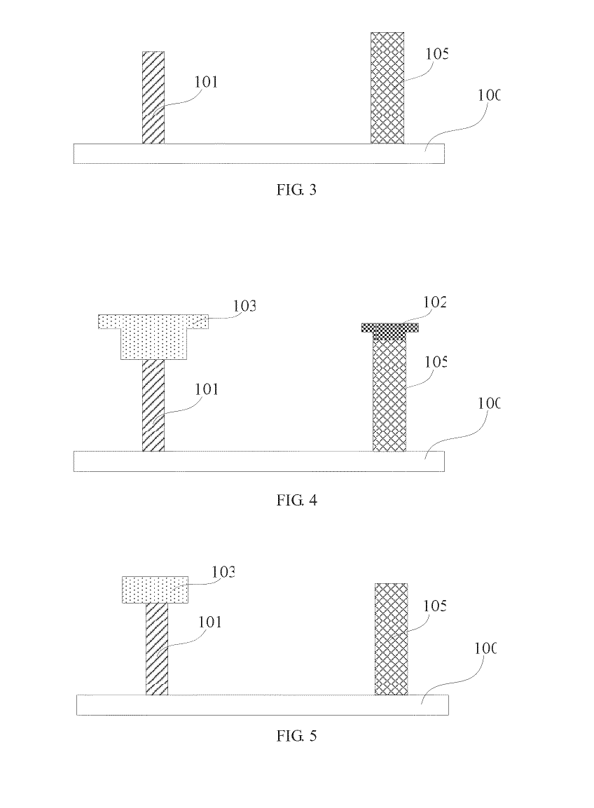

Please refer to FIG. 2, which is a schematic flowchart of a fabrication method of a phase change memory cell provided by the present invention in embodiment 1. As shown in FIG. 2, said fabrication method comprises the following steps of:

S10, providing a semiconductor substrate and forming a first electrode layer and an extraction electrode on said semiconductor substrate;

S12, forming a phase change material layer on said first electrode layer and forming a high resistance material layer on said extraction electrode;

S14, grinding said phase change material layer and removing the high resistance material layer on said extraction electrode;

S16, forming a second electrode layer on said phase change material layer; and

S18, integrating said first and second electrode layers with control switches, driving circuits and peripheral circuits by said extraction electrode to form a phase change memory cell.

The present invention is further detailed below with reference to the accompanying drawings.

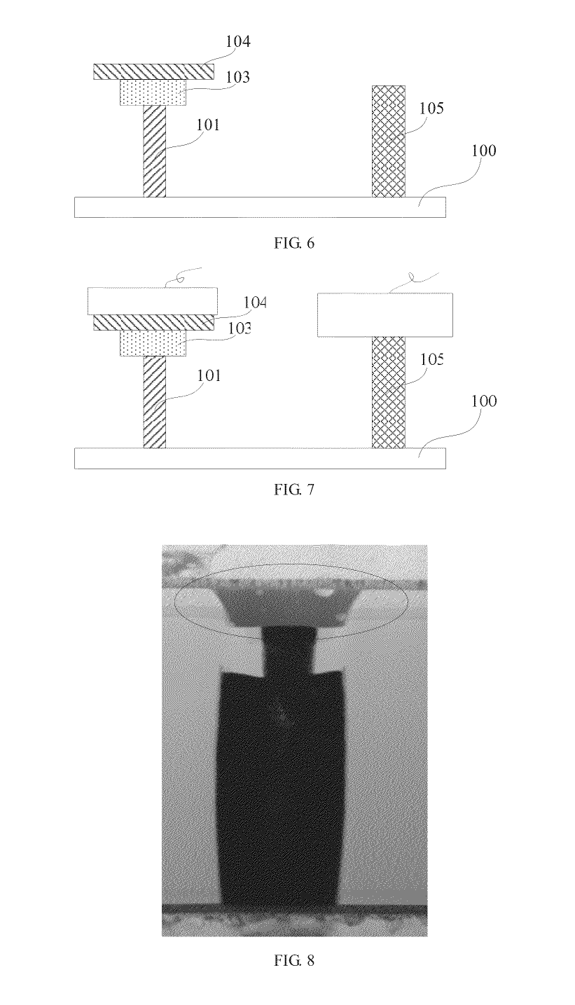

Firstly, carry out step S10 by providing a semiconductor substrate 100 and forming a first electrode layer 101 and an extraction electrode 105 on said semiconductor substrate 100 to form a structure as shown in FIG. 3.

Wherein, said semiconductor substrate 100 is silicon with semiconductor devices formed therein, silicon on insulator (SOI) with semiconductor devices formed therein, or II-VI or III-V compound semiconductor with semiconductor devices formed therein.

The first electrode layer 101 serves as the lower electrode, which can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The first electrode layer 101 is made of single metal material, such as any one of tungsten (W), platinum (Pt), aurum (Au), titanium (Ti), aluminum (Al), argentum (Ag), copper (Cu) or nickel (Ni), or is made of any one of the alloy, oxide, nitride or nitrogen oxide of the single metal material mentioned above.

In this embodiment, the first electrode layer 101 is made of tungsten (W) by chemical vapor deposition (CVD) with a diameter in the range of 10 nm to 70 nm and a thickness in the range of 50 nm to 200 nm.

In addition, the extraction electrode 105 can be formed be any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), and atomic layer deposition (ALD). The extraction electrode 105 is made of single metal material, such as any one of tungsten (W), platinum (Pt), aurum (Au), titanium (Ti), aluminum (Al), argentum (Ag), copper (Cu) or nickel (Ni), or is made of any one of the alloy, oxide, nitride or nitrogen oxide of the single metal material mentioned above.

In this embodiment, the extraction electrode 105 is made of aluminum (Al) by magnetron sputtering method with a thickness in the range of 300 nm to 500 nm.

In step S12, form a phase change material layer 103 on the first electrode layer 101 and form a high resistance material layer 102 on the extraction electrode 105 to form a structure as shown in FIG. 4. Specifically, the phase change material layer 103 can be formed on the first electrode layer 101 before the high resistance material layer 102 is formed on the extraction electrode 105, or the phase change material layer 103 can be formed on the first electrode layer 101 after the high resistance material layer 102 is formed on the extraction electrode 105, or the phase change material layer 103 can be formed on the first electrode layer 101 simultaneously when the high resistance material layer 102 is formed on the extraction electrode 105 (if process conditions permit).

Wherein, the phase change material layer 103 is formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The phase change material is any one of chalcogenide, germanium-antimony (GeSb) compound, silicon-antimony (SiSb) compound, germanium-antimony-tellurium (Ge—Sb—Te, GST) compound or metallic oxide.

In this embodiment, the phase change material layer 103 is a germanium-antimony-tellurium (Ge—Sb—Te, GST) compound, such as Ge₂Sb₂Te₅. Specifically, the Ge₂Sb₂Te₅ phase change material layer is formed by magnetron sputtering method with a Ge₂Sb₂Te₅ alloy target, wherein the process parameters are as the following: a base pressure of 1×10⁻⁵ Pa, a sputtering Ar pressure of 0.2 Pa, a sputtering power of 200 W, a substrate temperature of 25° C. The phase change material layer 103 has a thickness in the range of 300 nm to 500 nm.

The high resistance material layer 102 can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD); the high resistance material layer 102 has a resistance ten or more times that of the phase change material layer 103, and the high resistance material layer 102 is made of any one of the following: simple substance of main group IV, V and VI, alloy, oxide, nitride, carbide, nitrogen oxide.

In this embodiment, the high resistance material layer 102 is made of silicon dioxide (SiO2) with a thickness in the range of 10 nm to 50 nm, and preferably of 10 nm, 15 nm, 20 nm, 25 nm, 30 nm, 35 nm, 40 nm, 45 nm, 50 nm or etc. Obviously, in other embodiments, the high resistance material layer 102 can also be made of such as silicon carbide (SiC) or polysilicon.

In step S14, grind the phase change material layer 103 and remove the high resistance material layer 102 on the extraction electrode 105 to form a structure as shown in FIG. 5.

In this embodiment, the phase change material layer 103 is ground by chemical mechanical polishing to the extent that the phase change material is only remained in holes after the grinding of the phase change material layer 103. The high resistance material layer 102 on the extraction electrode 105 is removed by etching. Both chemical mechanical polishing and etching are technologies that those skilled in the art are familiar with and as such will not be discussed herein.

Step S16, form a second electrode layer 104 on the phase change material layer 103 after grinding to form a structure as shown in FIG. 6.

Wherein, the second electrode layer 104 serves as the upper electrode, which can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The second electrode layer 104 is made of single metal material, such as any one of tungsten (W), platinum (Pt), aurum (Au), titanium (Ti), aluminum (Al), argentum (Ag), copper (Cu) or nickel (Ni), or is made of any one of the alloy, oxide, nitride or nitrogen oxide of the single metal material mentioned above.

In this embodiment, the second electrode layer 104 is made of titanium nitride (TiN) by magnetron sputtering method, wherein the process parameters are as the following: a base pressure of 1×10⁻⁵ Pa, a sputtering pressure of 0.2 Pa, a gas flow ratio of Ar/N₂ of 1:1, a sputtering power of 300 W, a substrate temperature of 25° C. The second electrode layer 104 has a thickness in the range of 20 nm to 40 nm.

Step S18, integrate the first and second electrode layers 101 and 104 with other control switches and peripheral circuits by the extraction electrode 105 to form a phase change memory cell, as the structure as shown in FIG. 7.

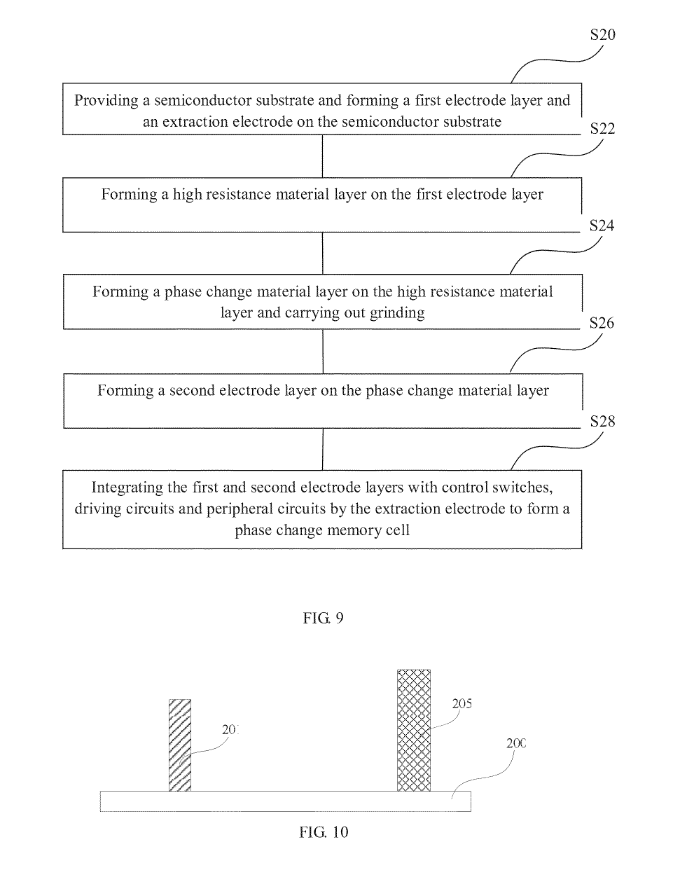

Please refer to FIG. 8 for the details of the phase change memory cell fabricated by the foregoing method. Because of the introduction of a high resistance material layer with a resistance ten or more times that of the phase change material layer, the phase change material layer can be protected from complete removal caused by phase change material over-corrosion during subsequent chemical mechanical polishing process. Compared with the prior art, this method enables well-preserved phase change material in the phase change material layer (as shown in FIG. 8, where the circled region is the phase change material layer) and thus enhances the yield of phase change memory cell. The test results show that, with reasonable parameters for testing, the resistance of the phase change memory cell can be successfully changed from low resistance to high resistance and the cycle life can be improved up to 10¹⁰ times, greatly enhancing the reliability.

### Embodiment 2

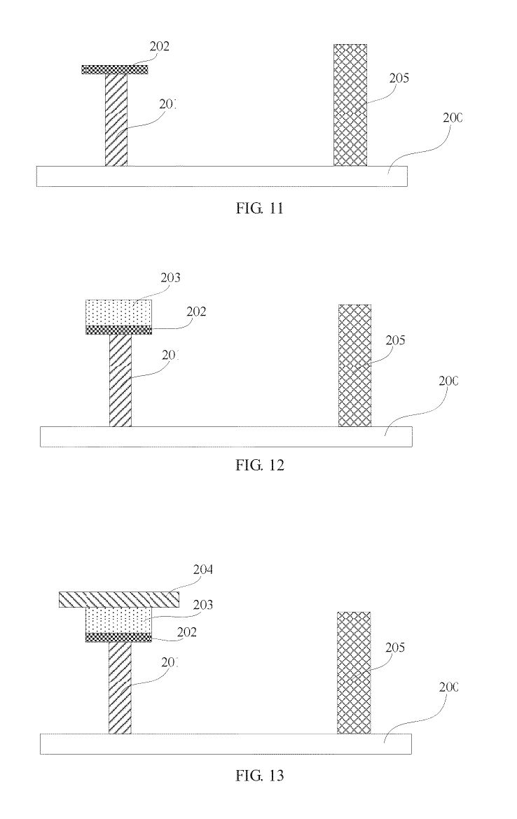

Please refer to FIG. 9, which is a schematic flowchart of a fabrication method of a phase change memory cell provided by the present invention in embodiment 2. As shown in FIG. 9, said fabrication method comprises the following steps of:

S20, providing a semiconductor substrate and forming a first electrode layer and an extraction electrode on said semiconductor substrate;

S22, forming a high resistance material layer on said first electrode layer;

S24, forming a phase change material layer on said high resistance material layer and carrying out grinding;

S26, forming a second electrode layer on said phase change material layer; and

S28, integrating said first and second electrode layers with control switches, driving circuits and peripheral circuits by said extraction electrode to form a phase change memory cell.

The present invention is further detailed below with reference to the accompanying drawings.

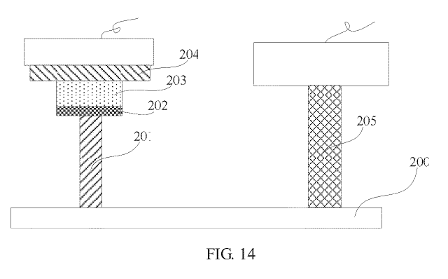

Firstly, carry out step S20 by providing a semiconductor substrate 200 and forming a first electrode layer 201 and an extraction electrode 205 on said semiconductor substrate 100 to form a structure as shown in FIG. 10.

Wherein, said semiconductor substrate 200 is silicon with semiconductor devices formed therein, silicon on insulator (SOI) with semiconductor devices formed therein, or II-VI or III-V compound semiconductor with semiconductor devices formed therein.

The first electrode layer 201 serves as the lower electrode, which can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The first electrode layer 201 is made of single metal material, such as any one of tungsten (W), platinum (Pt), aurum (Au), titanium (Ti), aluminum (Al), argentum (Ag), copper (Cu) or nickel (Ni), or is made of any one of the alloy, oxide, nitride or nitrogen oxide of the single metal material mentioned above.

In this embodiment, the first electrode layer 201 is made of tungsten (W) with a diameter in the range of 10 nm to 70 nm and a thickness in the range of 50 nm to 200 nm.

In addition, the extraction electrode 205 can be formed be any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), and atomic layer deposition (ALD). The extraction electrode 205 is made of single metal material, such as any one of tungsten (W), platinum (Pt), aurum (Au), titanium (Ti), aluminum (Al), argentum (Ag), copper(Cu) or nickel (Ni), or is made of any one of the alloy, oxide, nitride or nitrogen oxide of the single metal material mentioned above.

In this embodiment, the extraction electrode 205 is made of aluminum (Al) with a thickness in the range of 300 nm to 500 nm.

In step S22, form a high resistance material layer 202 on the first electrode layer 201 to form a structure as shown in FIG. 11.

Wherein, the high resistance material layer 202 can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD); the high resistance material layer 202 is made of any one of the following: simple substance of main group IV, V and VI, alloy, oxide, nitride, carbide, nitrogen oxide.

In this embodiment, the high resistance material layer 202 is made of silicon dioxide (SiO₂) with a thickness in the range of 1 nm to 10 nm, and preferably of 2 nm, 5 nm, 8 nm, 10 nm or etc. Obviously, in other embodiments, the high resistance material layer 202 can also be made of such as silicon carbide (SiC) or polysilicon.

In step S24, form a phase change material layer 203 on the high resistance layer 202 and carrying out grinding to form a structure as shown in FIG. 12.

Wherein, the phase change material layer 203 is formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The phase change material is any one of chalcogenide, germanium-antimony (GeSb) compound, silicon-antimony (SiSb) compound, germanium-antimony-tellurium (Ge—Sb—Te, GST) compound or metallic oxide.

In this embodiment, the phase change material layer 203 is a germanium-antimony-tellurium (Ge—Sb—Te, GST) compound, such as Ge₂Sb₂Te₅. Specifically, the Ge₂Sb₂Te₅ phase change material layer is formed by magnetron sputtering method with a Ge₂Sb₂Te₅ alloy target, wherein the process parameters are as the following: a base pressure of 1×10⁻⁵ Pa, a sputtering Ar pressure of 0.2 Pa, a sputtering power of 200 W, a substrate temperature of 25° C. The phase change material layer 203 has a thickness in the range of 300 nm to 500 nm.

The phase change material layer 203 is ground by chemical mechanical polishing to the extent that the phase change material is only remained in holes after grinding process.

In step S26, form a second electrode layer 204 on the phase change material layer 203 to form a structure as shown in FIG. 13.

Wherein, the second electrode layer 204 serves as the upper electrode, which can be formed by any one of the following: sputtering method, evaporation method, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), or atomic layer deposition (ALD). The second electrode layer 204 is made of single metal material, such as any one of tungsten (W), platinum (Pt), aurum (Au), titanium (Ti), aluminum (Al), argentum (Ag), copper (Cu) or nickel (Ni), or is made of any one of the alloy, oxide, nitride or nitrogen oxide of the single metal material mentioned above.

In this embodiment, the second electrode layer 204 is made of titanium nitride (TiN) by magnetron sputtering method, wherein the process parameters are as the following: a base pressure of 1×10⁻⁵ Pa, a sputtering pressure of 0.2 Pa, a gas flow ratio of Ar/N₂ of 1:1, a sputtering power of 300 W, a substrate temperature of 25° C. The second electrode layer 204 has a thickness in the range of 20 nm to 40 nm.

In step S28, integrate the first and second electrode layers 201 and 204 with other control switches, driving circuits and peripheral circuits by the extraction electrode 205 to form a phase change memory cell, as the structure as shown in FIG. 14.

The description of foregoing embodiments is only an illustrative description of the principle and function of the present invention but is not a limitation of the present invention. It is apparent to those skilled in the art that modifications can be made to the foregoing embodiments without deviating from the spirit and scope of the present invention. Accordingly, the protection scope of the present invention shall be as described in the claims.

What is claimed is:

1. A phase change memory cell, comprising a semiconductor substrate, and a first electrode layer, a phase change material layer and a second electrode layer that are sequentially located on said semiconductor substrate, and an extraction electrode located on said semiconductor substrate; characterized by also comprising a high resistance material layer used to prevent said phase change material layer from over-corrosion during the chemical mechanical polishing process, wherein said high resistance material layer has a resistance ten or more times that of the phase change material layer.

2. The phase change memory cell according to claim 1, characterized in that said high resistance material layer is located between said first electrode layer and said phase change material layer, or located on the extraction electrode of said first electrode layer.

3. The phase change memory cell according to claim 1, characterized in that said high resistance material layer is made of any one of the following: simple substance of main group IV, V and VI, alloy, oxide, nitride, carbide, nitrogen oxide.

4. The phase change memory cell according to claim 1, characterized in that said high resistance material layer has a thickness in the range of 1 nm to 50 nm.

5. A fabrication method of phase change memory cell, characterized by comprising the following steps of:
providing a semiconductor substrate and forming a first electrode layer and an extraction electrode on said semiconductor substrate;
forming a phase change material layer on said first electrode layer and forming a high resistance material layer on said extraction electrode, wherein said high resistance material layer has a resistance ten or more times that of the phase change material layer;
grinding said phase change material layer and removing the high resistance material layer on said extraction electrode;
forming a second electrode layer on said phase change material layer; and
integrating said first and second electrode layers with control switches, driving circuits and peripheral circuits by said extraction electrode to form a phase change memory cell.

6. The fabrication method of phase change memory cell according to claim 5, characterized in that said high resistance material layer is made of any one of the following: simple substance of main group IV, V and VI, alloy, oxide, nitride, carbide, nitrogen oxide.

7. The fabrication method of phase change memory cell according to claim 5, characterized in that said high resistance material layer has a thickness in the range of 10 nm to 50 nm.

8. A fabrication method of phase change memory cell, characterized by comprising the following steps of:
providing a semiconductor substrate and forming a first electrode layer and an extraction electrode on said semiconductor substrate;
forming a high resistance material layer on said first electrode layer;
forming a phase change material layer on said high resistance material layer and carrying out grinding, wherein said high resistance material layer has a resistance ten or more times that of the phase change material layer;
forming a second electrode layer on said phase change material layer; and
integrating said first and second electrode layers with control switches, driving circuits and peripheral circuits by said extraction electrode to form a phase change memory cell.

9. The fabrication method of phase change memory cell according to claim 8, characterized in that said high resistance material layer is made of any one of the following: simple substance of main group IV, V and VI, alloy, oxide, nitride, carbide, nitrogen oxide.

10. The fabrication method of phase change memory cell according to claim 8, characterized in that said high resistance material layer has a thickness in the range of 1 nm to 10 nm.
